(19) United States
(12) Patent Application Publication
(10) Pub. No.: US 2009/0098672 A1
(43) Pub. Date: Apr. 16, 2009

(54) Method for making a heat dissipating device for LED installation

(75) Inventor: Yaw-Huey Lai, Taipei County (TW)

Correspondence Address: BACON & THOMAS, PLLC, 625 SLATERS LANE, FOURTH FLOOR, ALEXANDRIA, VA, 22314-1176, US

(73) Assignee: TAI-SOL ELECTRONICS CO., LTD., TAIPEI CITY (TW)

(21) Appl. No.: 12/000,819

(22) Filed: Dec. 18, 2007

(30) Foreign Application Priority Data
Oct. 11, 2007 (TW) 96138070

(51) Int. Cl. H01L 33/00

(52) U.S. Cl. 438/26; 257/E33.058

(57) ABSTRACT

A method for making a heat dissipating device for LED installation, comprising the steps of a) preparing a thermal member having a metal surface, b) covering at least a part of the metal surface of the thermal member with a electrically insulative thermal conductivity layer, and c) providing multiple conducting layers at the electrically insulative thermal conductive layer for the installation of LED (light emitting diode) chips.

### BACKGROUND OF THE INVENTION

1. Field of the Invention

The present invention relates to heat dissipating devices and more particularly, to a method for making a heat dissipating device for use in LED installation.

2. Description of the Related Art

High brightness LEDs (light emitting diodes) produce much heat energy during operation. Therefore, how to solve heat dissipation problem during light emitting operation of LEDs is an important subject to people in this art.

U.S. Pat. No. 5,173,839, entitled “Heat-dissipating method and device for LED display, discloses a measure to solve heat dissipation problem. According to this measure, a strip of alumina is thermally bonded to the under surface of the LED display, a thermally conductive front panel is placed in thermal contact surrounding the front surface of the display, and a double sided, thermally conductive pressure-sensitive tape is used to bond a heatsink in thermal contact with the alumina. The heatsink is in thermal contact with the front panel and dissipates heat from the display via the alumina, the heatsink and the front panel. This measure is still not perfect. According to this measure, there are three layers of different substances set between the LED display and the heatsink. The multiple medium layers cause a high thermal resistance, lowering the heat dissipation speed.

Further, Taiwan Patent M313,759 discloses a technique of implanting LED chips to a heatsink so that heat can be directly transferred from the LED chip to the heatsink for quick dissipation. However, this design uses the heatsink as the common negative electrode for the LED chips that are connected in parallel, and the driving power must be of low voltage and high current. The control of this driving power is difficult. To eliminate this problem, the LED chips cannot use the heatsink as their commonly negative electrode, i.e., the LED chips must be connected in series.

### SUMMARY OF THE INVENTION

The present invention has been accomplished under the circumstances in view. It is one object of the present invention to provide a method for making a heat dissipating device for LED installation, which allows series connection of multiple LED chips and provides excellent heat dissipation effect.

To achieve this and other objects of the present invention, the method for making a heat dissipating device for LED installation includes the steps of a) preparing a thermal member having a metal surface, b) covering at least a part of the metal surface of the thermal member with a electrically insulative thermal conductivity layer, and c) providing multiple conducting layers at the electrically insulative thermal conductive layer for the installation of LED (light emitting diode) chips. Thus, the conducting layers are adapted for installation of multiple LED chips, and the heat dissipating device dissipates heat from the LED chips rapidly during their operation.

Further, the formation of the conducting layers can be achieved by coating a conducting material on the electrically insulative thermal conductive layer and then removing a part of the conducting material from the electrically insulative thermal conductive layer. Alternatively metal rings can be directly fastened to the electrically insulative thermal conductive layer at different locations, forming the desired conducting layers.

### BRIEF DESCRIPTION OF THE DRAWINGS

FIG. 1 is a schematic drawing showing members for a heat dissipating device according to a first embodiment of the present invention.

FIG. 2 corresponds to FIG. 1, showing the electrically insulative thermal conductivity layer covered on the thermal member.

FIG. 3 corresponds to FIG. 2, showing the conducting layer covered on the electrically insulative thermal conductivity layer.

FIG. 4 corresponds to FIG. 3, showing a part of the conducting layer removed and independent sub-conducting layers left on the electrically insulative thermal conductivity layer.

FIG. 5 corresponds to FIG. 4, showing LED chips installed in the sub-conducting layers and the thermal member connected to a heatsink.

FIG. 6 is a sectional view in an enlarged scale of a part of FIG. 5.

FIG. 7 illustrates individual LED chips respectively installed in the sub-conducting layers of a heat dissipating device constructed according to a second embodiment of the present invention and the thermal member of the heat dissipating device connected to a heatsink.

FIG. 8 illustrates multiple LED chips installed in each sub-conducting layers of a heat dissipating device constructed according to a second embodiment of the present invention and the thermal member of the heat dissipating device connected to a heatsink.

### DETAILED DESCRIPTION OF THE INVENTION

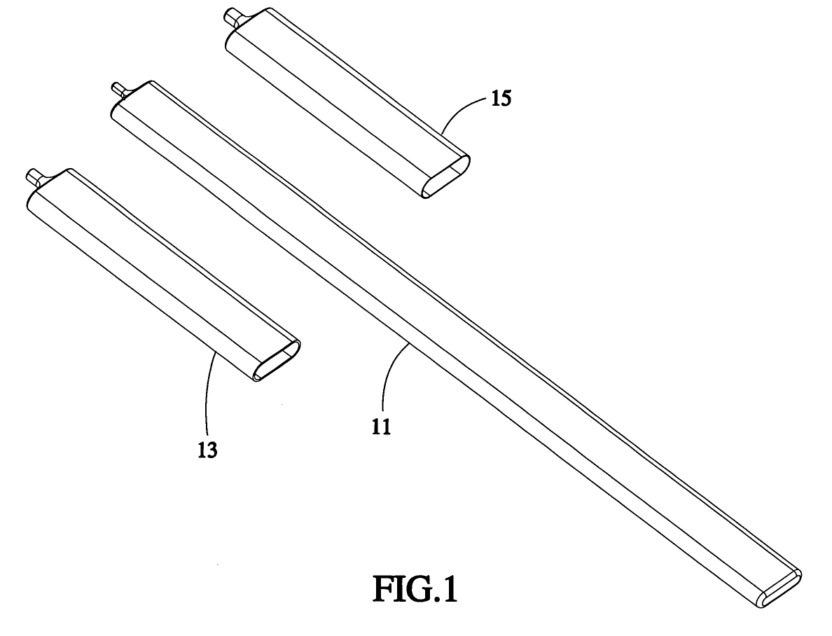

Referring to FIGS. 1˜4, a method of making a heat dissipating device for LED installation in accordance with a first embodiment of the present invention includes the steps of:

a) Prepare a thermal member 11 having a metal surface. The thermal member 11 can be a liquid/gas phase heat dissipating device, for example, a heat tube or flat heat tube. Alternatively, the thermal member 11 can be a heatsink. A heatsink is a popularly used known product, therefore it is not illustrated here. According to this embodiment, the thermal member 11 is a heat tube.

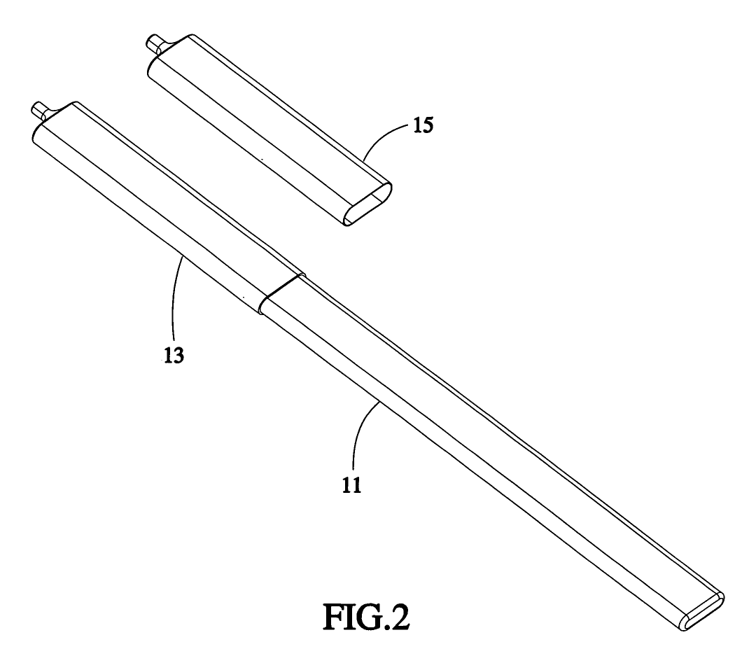

b) Cover at least a part of the metal surface of the thermal member 11 with an electrically insulative thermal conductivity layer 13. According to this embodiment, the electrically insulative thermal conductivity layer 13 is epoxy resin and covers the front half of the metal surface of the thermal member 11, as shown in FIG. 2.

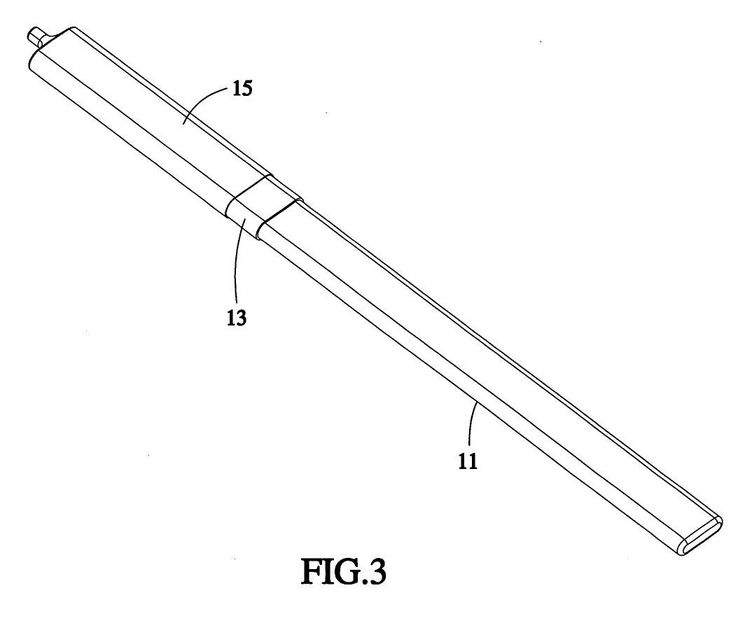

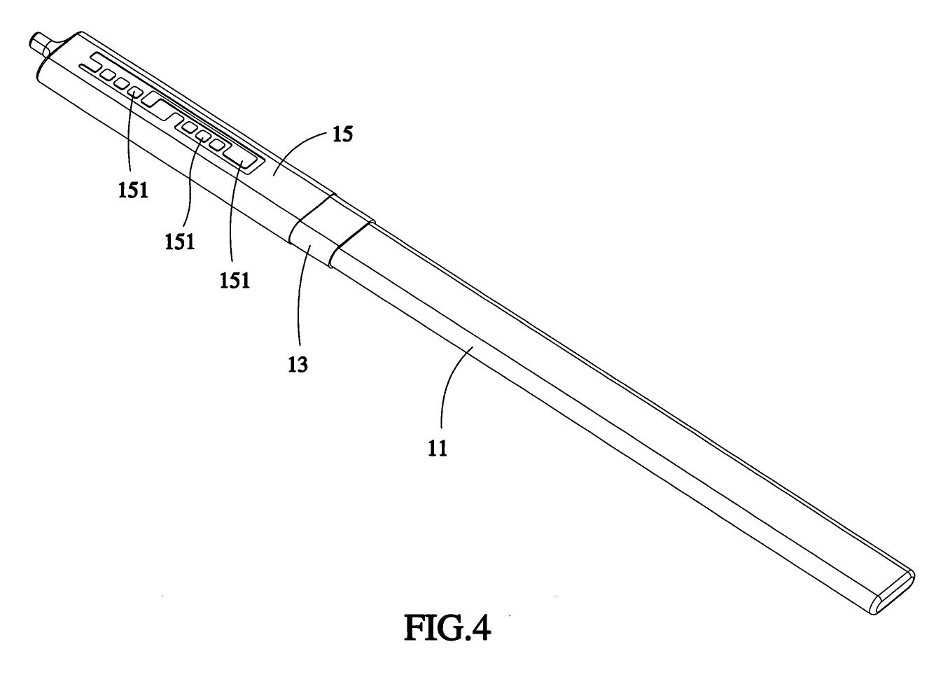

c) Cover the electrically insulative thermal conductivity layer 13 with a conducting layer 15. According to this embodiment, the conducting layer 15 a metal material, for example, copper covered on the electrically insulative thermal conductivity layer 13, as shown in FIG. 3. After covering of the conducting layer 15 on the electrically insulative thermal conductivity layer 13, the conducting layer 15 is partially removed from the electrically insulative thermal conductivity layer 13, forming a plurality of independent sub-conducting layers 151 for the installation of LEDs. According to this embodiment, the area of the conducting layer 15 to be kept is covered with mask means, and then the conducting layer 15 is washed with a cleaning agent (for example, copper sulfate solution) to remove the part of the conducting layer 15 beyond the mask means. This procedure is similar to the conventional circuit board cleaning process. Alternatively, a laser-engraving technique may be employed to remove a part of the conducting layer 15. FIG. 4 shows the status of the conducting layer 15 partially removed and the desired independent sub-conducting layers 151 left on the electrically insulative thermal conductivity layer 13.

By means of the aforesaid procedure, multiple independent sub-conducting layers 151 are formed on the thermal member 11 and electrically insulated from one another.

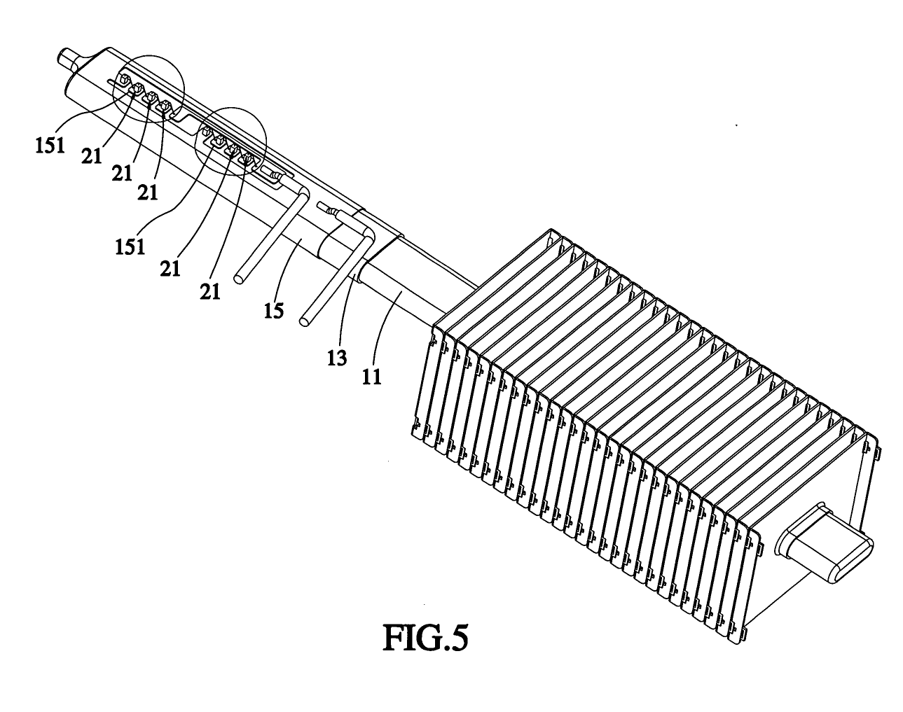

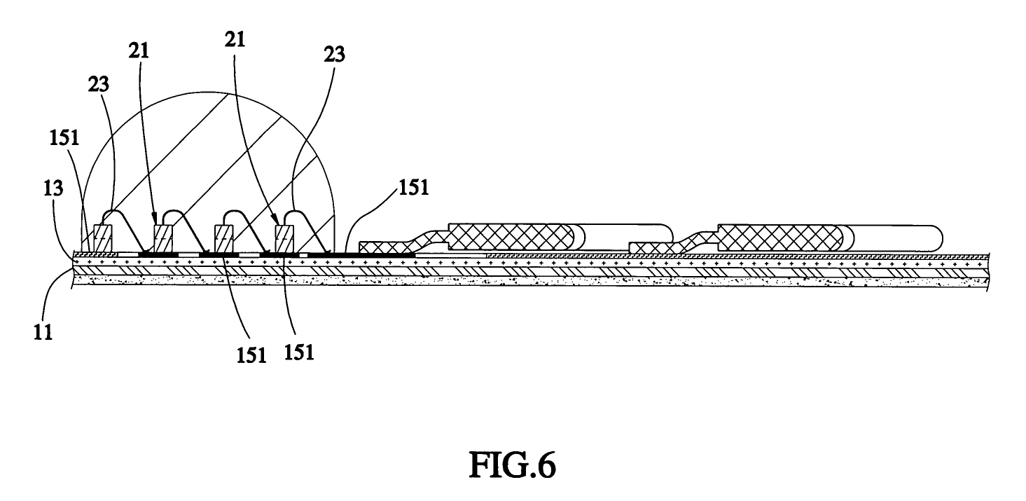

During LED installation, the negative electrodes of the prepared LED chips 21 are respectively bonded to the sub-conducting layers 151, and the positive electrode of each LED chip 21 is connected to the negative electrode of another LED chip 21 or another sub-conducting layer 151 via a lead wire 23, and therefore, the LED chips 21 are connected in series, as shown in FIGS. 5 and 6. As illustrated in FIGS. 5 and 6, the electrically insulative thermal conductivity layer 13 is disposed beneath the sub-conducting layers 151 to isolate the sub-conducting layers 151 from the thermal member 11, preventing a short circuit. Further, the electrically insulative thermal conductivity layer 13 and the sub-conducting layers 151 have the characteristic of high thermal conductivity for quick transfer of heat energy from the LED chips 21 to the thermal member 11.

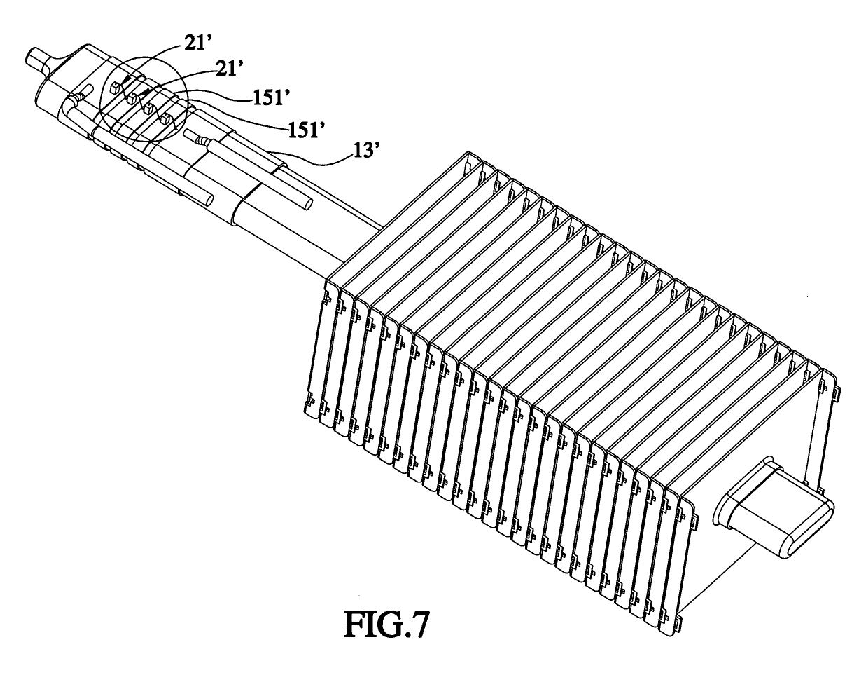

FIG. 7 illustrates a heat dissipating structure constructed according to a second embodiment of the present invention. This second embodiment is substantially similar to the aforesaid first embodiment with the exception of the formation of the sub-conducting layers 151′ in step c). According to this embodiment, metal rings are mounted on the electrically insulative thermal conductivity layer 13 at the desired locations, forming the desired sub-conducting layers 151′. FIG. 7 also illustrates installation of LED chips 21′.

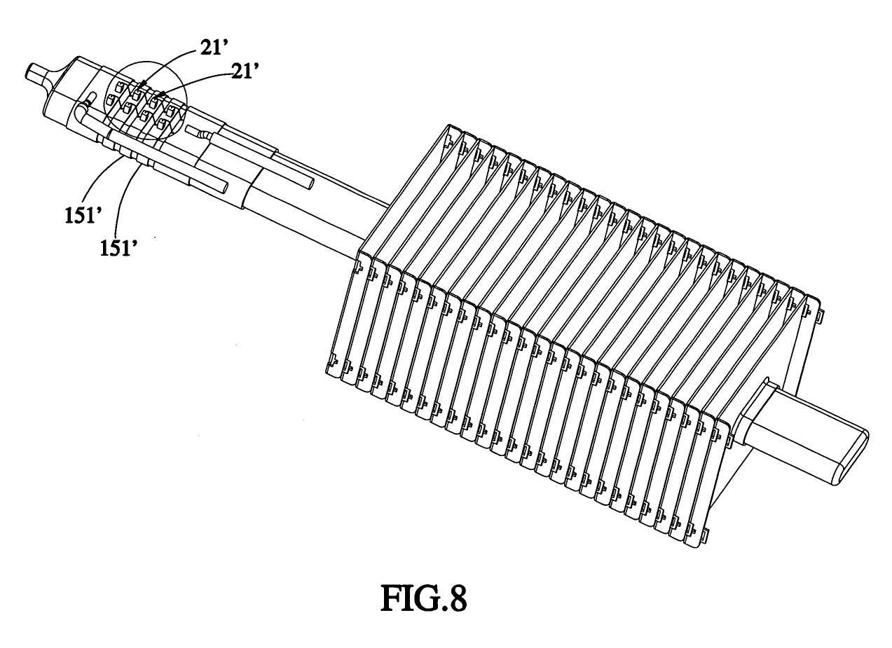

Referring to FIG. 8, each sub-conducting layer (metal ring) 151′ has two LED chips 21′ connected thereto in a parallel manner, and the LED chips 21′ at one sub-conducting layer (metal ring) 151′ are connected in series to the LED chips 21′ at another sub-conducting layer (metal ring) 151′. This figure explains that each sub-conducting layer (metal ring) 151′ can be mounted with one single LED chip 21′, and can also be mounted with multiple LED chips 21′.

In the aforesaid two embodiments, one sub-conducting layer 151 or 151′ is not limited to the installation of one single LED chip 21 or 21′ only. Multiple LED chips 21 or 21′ can be installed in one sub-conducting layer 151 or 151′ in a parallel manner, i.e., the LED chips 21 or 21′ at one sub-conducting layer 151 or 151′ are connected in parallel and the LED chips 21 or 21′ at one sub-conducting layer 151 or 151′ are connected in series to LED chips 21 or 21′ at another sub-conducting layer 151 or 151′.

In practice, the packaged LED chips 21 or 21′ should be indicated by imaginary line. However, because an imaginary line cannot be well seen, a solid line is used to indicate the packaged LED chips 21 or 21′ in FIGS. 5˜7.

As stated above, the invention allows series connection of LED chips and almost direct arrangement of LED chips on the thermal member 11, providing an excellent heat dissipation effect.

Although particular embodiments of the invention have been described in detail for purposes of illustration, various modifications and enhancements may be made without departing from the spirit and scope of the invention. Accordingly, the invention is not to be limited except as by the appended claims

What is claimed is:

1. A method for making a heat dissipating device for LED installation, comprising the steps of:
a) preparing a thermal member, said thermal member having a metal surface;
b) covering at least a part of the metal surface of said thermal member with an electrically insulative thermal conductivity layer; and
c) providing multiple conducting layers at said electrically insulative thermal conductive layer for the installation of LED (light emitting diode) chips.

2. The method as claimed in claim 1, wherein the step c) providing multiple conducting layers at said electrically insulative thermal conductive layer for the installation of LED (light emitting diode) chips is to coat an electrically conducting material on said electrically insulative thermal conductive layer and then to remove a part of said electrically conducting material from said electrically insulative thermal conductive layer, thereby forming said multiple conducting layers on said electrically insulative thermal conductive layer.

3. The method as claimed in claim 2, wherein the removal of a part of said electrically conducting material from said electrically insulative thermal conductive layer is achieved by means of the application of a cleaning agent.

4. The method as claimed in claim 3, wherein said electrically conducting material is a metal material; said cleaning agent is copper sulfate solution; removal of a part of said electrically conducting material from said electrically insulative thermal conductive layer is achieved by means of covering the part of said electrically conducting material to be left with copper sulfate-resistant mask means and then washing said electrically conducting material with copper sulfate solution.

5. The method as claimed in claim 2, wherein the removal of a part of said electrically conducting material from said electrically insulative thermal conductive layer is achieved by means of the application of a laser-engraving technique.

6. The method as claimed in claim 1, wherein the step c) providing multiple conducting layers at said electrically insulative thermal conductive layer for the installation of LED (light emitting diode) chips is to fasten multiple metal rings to said electrically insulative thermal conductive layer at selected locations.

7. The method as claimed in claim 1, wherein said thermal member is a liquid/gas phase thermal member.

8. The method as claimed in claim 7, wherein said liquid/gas phase thermal member is a thermal tube.

9. The method as claimed in claim 1, wherein said thermal member is a heatsink.

10. The method as claimed in claim 1, wherein said electrically insulative thermal conductivity layer is epoxy resin.
